(19) United States
(12) Patent Application Publication
(10) Pub. No.: US 2012/0169322 A1
(43) Pub. Date: Jul. 5, 2012

(54) PHASE IDENTIFICATION SYSTEM AND METHOD

(75) Inventors: Amol Rajaram Kolwalkar, Bangalore (IN); Pradeep Vijayan, Bangalore (IN); Rajendra Naik, Bangalore (IN)

(73) Assignee: GENERAL ELECTRIC COMPANY, SCHENECTADY, NY (US)

(21) Appl. No.: 12/980,866

(22) Filed: Dec. 29, 2010

(51) Int. Cl. G01R 25/00

(52) U.S. Cl. 324/86

(57) ABSTRACT

A phase identification system includes a power distribution station comprising a phase distortion device to generate distortions at cross over points of at least two pairs of three phase voltages and a phase detection device to receive one of the three phase voltages and to identify a phase of the received voltage based on a characteristic of a distortion in the received voltage.

### BACKGROUND

The present invention relates generally to the field of three-phase power distribution networks. More specifically, the invention relates to the field of identifying the phase of a power line in a three-phase power distribution network.

Modern power distribution systems often deliver three phase voltage to users. That is, a power line may, for example, include a plurality of conductors each designated as a specific phase of voltage. Moreover, the power distribution system may be set up to operate such that the loads of the power line are balanced (e.g., the amount of power drawn from each phase output of, for example, a three-phase transformer, is equal). However, over time, users may be added and removed from the network, which may result in an imbalance in the phase currents and voltage flow. That is, too many users may be connected to one phase of voltage while too few are connected to a second and/or third phase. This may result in a non-optimal utilization of the existing infrastructure. One manner of overcoming this load imbalance may be to institute a rebalancing of the loads, for example, by moving customers from a more highly used phase of voltage to a lesser used phase of voltage.

However, challenges exist in moving customers from one phase of voltage to another. For instance, as customers are added to and subtracted from a power distribution network, the phase of voltage that a given customer is connected to may be difficult to ascertain without costly physical tracking (typically by a worker in the field) of a given power line to the network. That is, while a load imbalance may be detected remotely, the phase to which the individual users are connected to may not be readily apparent without physically tracking the power lines from a substation to the respective user locations. Accordingly, it would be advantageous to ascertain the phase of voltage to which a user is connected to without sending a person to one or more user sites to physically determine the voltage phase being received at the various sites. Further, identifying correct phase of the loads enables differentiation between single phase and three phase faults and in turn enables the accuracy of outage management systems that rely on the phase information.

One of the methods of identifying phase is using modems and telephone lines to establish a communication link. A signal associated with the phase at a point in the network where the phase of the line is known (the reference line) is transmitted over the communication link to a point in the network where the phase of the line is not known (the line under test). In another method, radio signals are used instead of modems and telephone lines for communication. However, both these techniques require calibration procedures and special training to be used effectively. An additional method of measuring the phase is by means of precise time stamped measurements (usually using GPS) at the substation (where the phase is known) and at the remote location where phase is unknown. By estimating the phase difference between the two signals, the phase at the remote location can be determined. However, this method needs two-way communications or information at two different locations to identify the phase.

Accordingly, there is a need to provide an improved apparatus and method for the identification of line phase of a power line in a power distribution network.

### BRIEF DESCRIPTION

In accordance with an embodiment of the present invention, a phase identification system is provided. The system includes a power distribution station comprising a phase distortion device for generating distortions at cross over points of at least two pairs of three phase voltages. The system also includes a phase detection device for receiving one of the three phase voltages and detecting a phase of the received voltage based on a characteristic of the distortion in the received voltage.

In accordance with another embodiment of the present invention, a method of identifying phase is provided. The method includes receiving a distorted voltage from a power distribution system, wherein the distorted voltage was formed by distorting three phase voltages of the power distribution system near cross over points of at least two different pairs of the three phase voltages. The method also includes determining information regarding a phase of the received distorted voltage based on a characteristic of the distortion in the received distorted voltage.

### DRAWINGS

These and other features, aspects, and advantages of the present invention will become better understood when the following detailed description is read with reference to the accompanying drawings in which like characters represent like parts throughout the drawings, wherein:

FIG. 1 is a block diagram of a power grid, in accordance with an embodiment of the present invention;

FIG. 2 is a block diagram of a phase detection device of the power grid of FIG. 1, in accordance with an embodiment of the present invention;

FIG. 3 is a block diagram of a power distribution station of the power grid of FIG. 1, in accordance with an embodiment of the present invention;

FIG. 4 is a diagrammatical representation of a phase identification system utilizing a step down transformer; and

FIG. 5 is a graphical representation of distorted voltage signals in accordance with an embodiment of the present invention.

### DETAILED DESCRIPTION

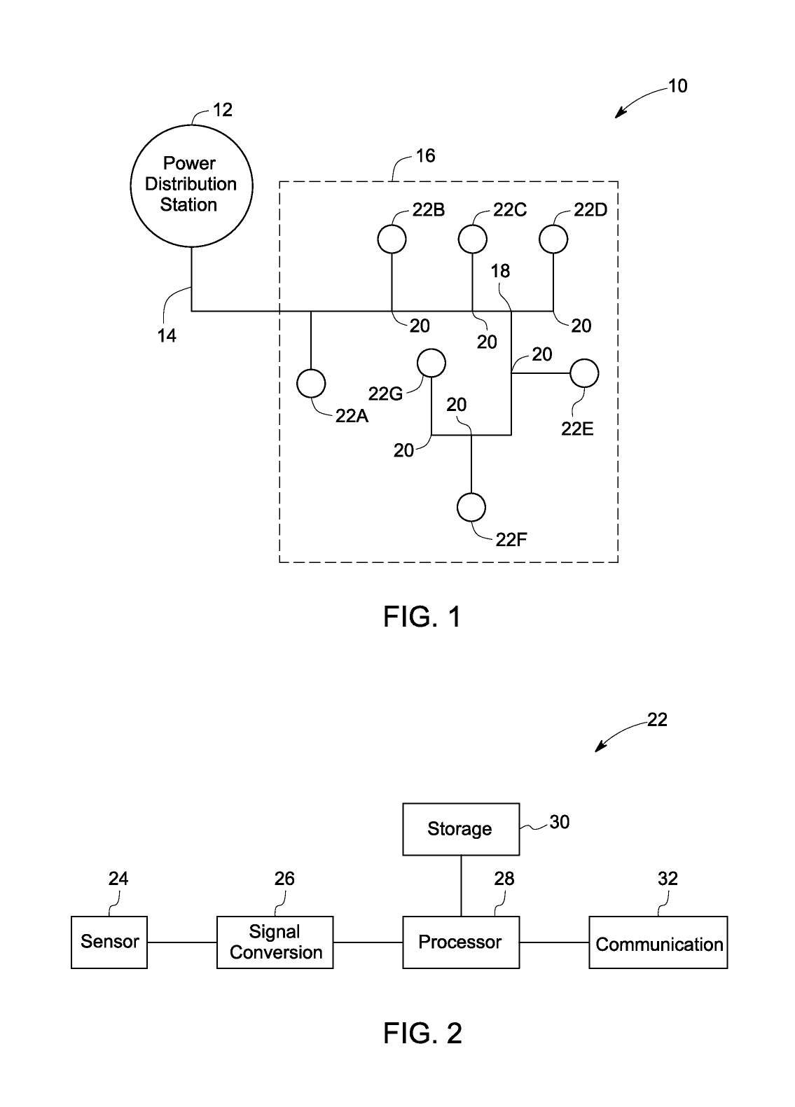

FIG. 1 illustrates a power grid 10 that may operate to provide voltage from a power distribution station 12. The power distribution station 12 may, for example, include a power plant including one or more power generators that may generate voltage for transmission on the power grid 10. Additionally, or alternatively, the power distribution station may include one or more power substations that may include one or more transformers that operate to transform voltage from one voltage to another (e.g., step-down received voltages from, for example, 100,000 volts to less than 10,000 volts) and/or one or more distribution busses for further routing the power. The power distribution station 12 may also be connected to a power distribution network 16 via, for example, one or more power lines 14.

In one embodiment, the power lines 14 may include a plurality of transmission paths for transmission of power from the power distribution station 12 to the power distribution network 16. For example, the power lines 14 may transmit voltage in three phases, e.g. phases A-C. Additionally, the power lines 14 may include a neutral line in addition to the paths for transmission of the three phases of voltage.

The power distribution network 16 may distribute the three phase voltage to a plurality of users. The distribution network 16 may include, for example, one or more taps 18. The one or more taps may operate to split off one or more of the power lines 14 to, for example, a side street on which one or more users reside. The tap 18 may thus operate to split one or more of the voltage phases A-C to the users on this side street. The power distribution network 16 may also include user lines 20. The user lines 20 may operate as direct connections to the power lines 14. That is, each user line 20 may include, for example, a transformer for stepping down the voltage from approximately 7200 volts to approximately 240 volts. Additionally, it should be noted that each of the user lines 20 may be connected to a single phase of voltage. That is, each user line 20 may be connected to phase A, phase B, or phase C voltage. The 240 volt phase A, phase B, or phase C voltage may be transmitted to a user with meters 22A-22G connected in the circuit.

Each of the meters 22A-22G (e.g., phase detection devices) may operate to monitor the amount of energy being transmitted to and consumed by a particular user. In one embodiment, one or more of the meters 22A-22G may be a portion of an advanced metering infrastructure (AMI) such that the meters 22A-22G may measure and record usage data in specified amounts over predetermined time periods (such as by the minute or by the hour), as well as transmit the measured and recorded information to the power distribution station 12. In another embodiment, the meters 22A-22G may allow for transmission of additional information, such as power outages, voltage phase information, or other infrastructure information, to be sent to the power distribution station 12 for assessment.

FIG. 2 illustrates a block diagram of one of the meters 22, which may be representative of any of the meters 22A-22G. As illustrated, the meter 22 may include a sensor 24, signal conversion circuitry 26, one or more processors 28, storage 30, and communication circuitry 32. In conjunction, the sensor 24, the signal conversion circuitry 26, one or more processors 28, the storage 30, and the communication circuitry 32 may allow the meter 22 to determine and transmit a signal indicative of the phase of voltage being received at the meter 22. In this manner, the meter 22 may operate as a phase detection device. Meter 22, in one embodiment, is physically attached at the location where the power is being used. Additionally or alternatively, the phase detection device may comprise a hand-held metering device, and the determination and/or transmission of a signal indicative of the phase of voltage being received may be accomplished by the hand-held metering device. In one embodiment, the sensor 24 may include electrical components for receiving and measuring the current and voltage from the user line 20. As noted above, this voltage may be in one of three phases, phase A, phase B, or phase C, each 120 degrees out of phase with one another. The sensor 24 may transmit the detected voltage and/or current as a signal to the signal conversion circuitry 26. Additionally, the sensor 24 may detect distortions in voltage signals at the meter 22. As will be discussed in greater detail below, the distortions in voltage signals may be used to obtain a determination of the received phase of voltage at the meter 22.

Also illustrated in FIG. 2 is signal conversion circuitry 26. The signal conversion circuitry 26 may include, for example, voltage conversion circuitry 26 to convert the voltage of the signal received from the sensor 24 from 240 volts to approximately 5 volts or less. Additionally, the voltage conversion circuitry may, for example, include at least one analog to digital converter for transforming signals received from the sensor 24 (such as voltage signals or injected signals) from analog form into digital signals for processing by one or more processors 28.

The one or more processors 28 may provide the processing capability for the meter 22. The one or more processors 28 may include one or more microprocessors, such as one or more “general-purpose” microprocessors, one or more special-purpose microprocessors and/or ASICS, or some combination of such processing components. Additionally, programs or instructions executed by the one or more processors 28 may be stored in any suitable media that includes one or more tangible, computer-readable media at least collectively storing the executed instructions or routines, such as, but not limited to, the storage device described below. As such, the meter 22 may include programs encoded on a computer program product (such as storage 30), which may include instructions that may be executed by the one or more processors 28 to enable the meter 22 to provide various functionalities, including determining the phase of voltage received at the meter 22 based on, for example, distortions in the voltage signal.

The instructions and/or data to be processed by the one or more processors 28 may be stored in a computer-readable medium, such as storage 30. The storage 30 may include a volatile memory, such as random access memory (RAM), and/or a non-volatile memory, such as read-only memory (ROM). In one embodiment, the storage 30 may store firmware for the meter 22 (such as various programs, applications, or routines that may be executed on the meter 22). In addition, the storage 30 may be used for buffering or caching during operation of the meter 22. The storage 30 may include, for example, flash memory, a hard drive, or any other optical, magnetic, and/or solid-state storage media. The storage 30 may also be used to store information for eventual transmission via communication circuitry 32. The information stored may include the phase information that can be used later for example during meter reading by the utility.

Communication circuitry 32 may be utilized to transmit information from the meter 22 to, for example, the power distribution station 12 (FIG. 1). The information may, for example, include one or more signals indicating the phase of voltage being received at the meter 22, the voltage usage at the meter 22, and/or other information relating to the operation of the meter 22. Accordingly, the communication circuitry 32 may include, for example, a transceiver for transmitting and receiving information with the power distribution station 12 and/or other meters (e.g., 22A-22G). The communication circuitry 32 may, instead, include a transmitter, which may allow for transmission of information to, for example, the power distribution station 12 and/or other meters, but will not receive information. The communication circuitry 32 may further include wireless transmission and/or transceiver elements for wireless transmission and/or reception of information. Additionally and/or alternatively, the communication circuitry 32 may be physically coupled to the power distribution station 12 through a wired communication mode, power line carrier communication (PLC) circuitry, for example. Regardless of the transmission medium, through the use of communication circuitry 32, the meter 22 may be able to transmit collected information including the phase of voltage being received at the meter 22.

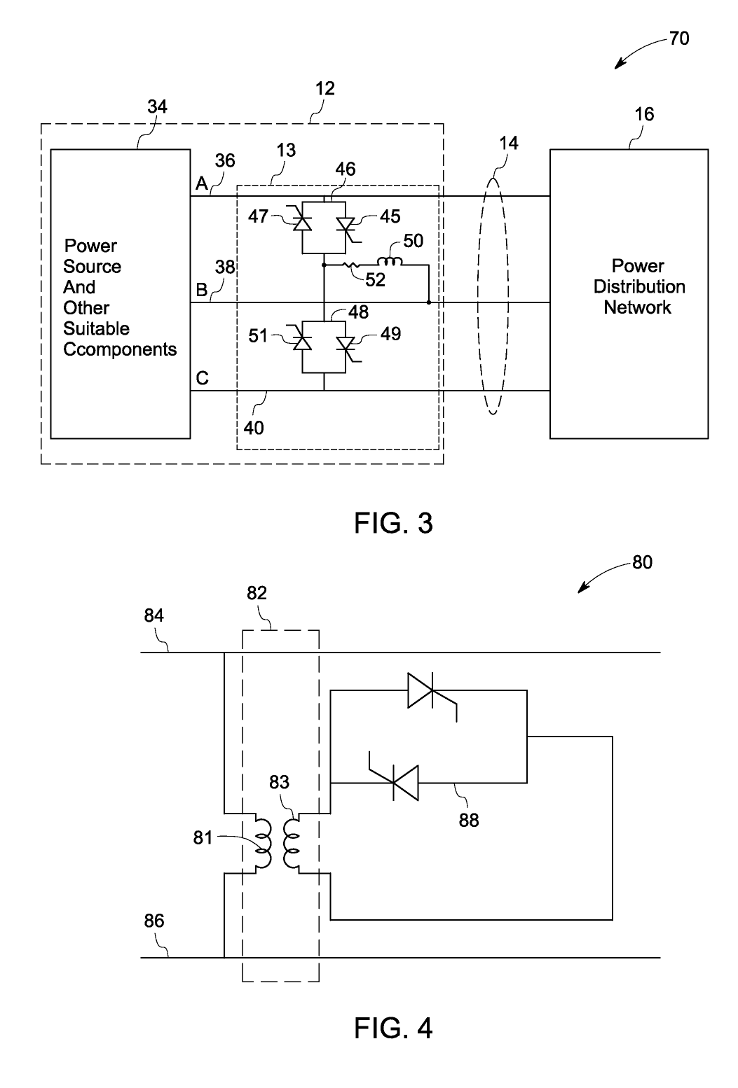

FIG. 3 is a block diagram 70 of a power distribution station 12 with a phase distortion device 13 that may be utilized in conjunction with the meters 22 to determine the phase of voltage being supplied to a given user. The power distribution station 12 may include a power source and other suitable components 34 for power delivery such as transformers, meters and switchgear components. This power source may include, for example, a power generator or one or more transformers, as discussed above. The power source 34 may operate to transmit three phase voltage across power lines 14, such that phase A voltage may be transmitted across line 36, phase B voltage may be transmitted across line 38, and phase C voltage may be transmitted across line 40. It should be noted that the phase line labeling of phase A, phase B, and phase C for lines 36, 38, and 40 is only for purposes of example. In one embodiment, the phase distortion device 13 may operate to distort the phase voltage signals. The phase voltage signals may be distorted either on command or on a schedule. For example, a utility may initiate a distortion in response to the amount of unbalance seen in the network. Additionally or alternatively, the distortion may occur a constant frequency such as, for example at a particular time every day. The distorted phase voltages are transmitted over lines 36, 38, 40 and reach meter 22 (FIG. 1) in power distribution network 16, and meter 22 identifies the distortion and hence the phase depending on a characteristic of the distortion received. In one embodiment, the meter 22 may also transmit the identified phase information to the power distribution station 12 (FIG. 1).

Distortions in voltage signals may be created in any one of a number of ways. In one embodiment, the distortions in the voltage signals may be created by short circuiting two phases momentarily (for example, less than ⅙^{th} of the time period of the voltage waveform) through an inductor or a resistor inductor pair. In one embodiment, a momentary short circuit may be achieved by using solid state devices 46, 48 and an inductor 50 or a resistor 52-inductor 50 pair. In the embodiment of FIG. 3, solid state devices 46, 48 are shown as a pair of antiparallel thyristors. However, in one embodiment, a single thyristor in upside down or downside up mode may also be used instead of an antiparallel thyristor pair to reduce the part count and to create distortions in only one half cycle of the voltage waveform. Other solid state devices 46, 48 include Metal Oxide Semiconductor Field Effect Transistors (MOSFETs), Insulated Gate Bipolar Transistor (IGBTs), and Gate Turn Off Thyristors (GTOs). Solid state devices 46, 48 may comprise a material such as silicon carbide (SiC) in one embodiment, for example. In one embodiment, a solid state device may comprise multiple low voltage solid state devices connected in series to increase the voltage rating. In one embodiment, solid state device 46 may comprise a pair of antiparallel thyristors 45 and 47 connected between two phases 36, 38 along with a resistor inductor pair (52, 50) to create distortions in the phase A and phase B voltages. Similarly, solid state device 48 may comprises a pair of antiparallel thyristors 49 and 51 connected between phases 38 and 40 along with the resistor inductor pair to create distortions in phase C and phase B voltages. In the embodiment of FIG. 3, a common resistance inductor pair is used for both solid state devices 46 and 48, however, in certain embodiments, a separate resistor inductor pair for each of the devices 46 and 48 may be used. To generate the distortion, in one embodiment wherein the solid state devices comprise thyristor pairs, one of the thyristors in a thyristor pair may be fired (turned on) near the cross-over of the two phase voltage signals. For example, thyristor 45 may be fired near the cross over point of the phase A voltage signal and the phase B voltage signal, whereas thyristor 51 may be fired near the cross over of the phase C and phase B voltage signals. In one embodiment, the term “near the cross over point” refers to any phase angle within 60° before the cross over point. It should be noted here that the cross over point refers to the point where two phase voltage signals cross each other. Switching near the cross-over points helps in reducing the voltage difference across the inductor 50 and hence reduces the current. The instant (or degree/point in the waveform) of the firing of the thyristor also affects the amount of distortion caused in the network and may be used for tuning the signal for easier detection. For example, if the thyristor is fired at 30° rather than at 45° phase displacement before the cross over point of the phase voltages, then the distortions in the phase voltages will be less. After firing, the thyristors may be turned off automatically. The short circuit is opened up when the current through a thyristor becomes zero and the voltage across the thyristor becomes negative.

In one embodiment 80, as shown in FIG. 4, thyristors with lower voltage ratings may be utilized for creating distortions in the phase voltages. In such an embodiment, a step down voltage transformer 82 may be utilized between a pair of the three phases 84, 86 with a primary winding or a high voltage winding 81 connected across two phases 84, 86 and a secondary winding or a low voltage winding 83 connected across a thyristor pair 88. When the phases 84, 86 are to be short circuited for creating a distortion in voltages, one of the thyristors in thyristor pair 88 is turned ON and the short circuit on secondary winding 83 is reflected on primary winding 81, thus generating voltage distortion. During normal condition, low voltage winding 83 is kept open. Further, in this embodiment, the leakage inductance of the transformer can act as an inductor rather than using a separate inductor. In one embodiment, a single thyristor may be used rather than thyristor pair 88 for creating distortions in only one half cycle of the voltage waveform and to reduce the part count.

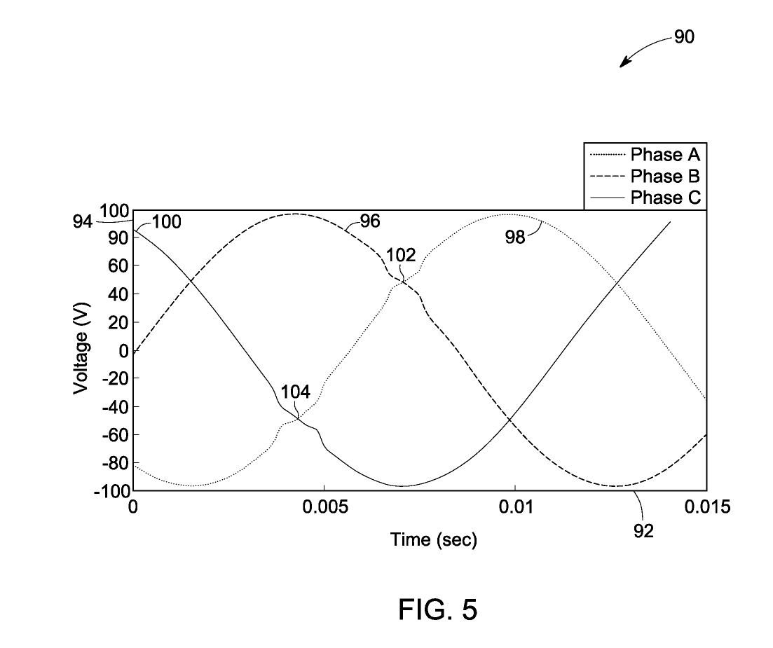

FIG. 5 is a simulation plot 90 of distorted voltage signals in accordance with an embodiment of the present invention. Horizontal axis 92 represents time in seconds and vertical axis 94 represents voltage in volts. Plot 90 shows three voltage signals, phase A voltage signal 96, phase B voltage signal 98 and phase C voltage signal 100. As described with respect to FIG. 3, in one embodiment, thyristor 45 is fired near the cross over of voltage signals of phase A and phase B, and similarly thyristor 51 is fired near cross over of voltage signals of phase C and phase B. Thus, there are two voltage distortions 102 and 104 near cross over of phase A and phase B and cross over of phase B and phase C respectively. Each of the meters 22 may receive these distorted voltage signals and use the distortions to detect the phase to which they are connected depending on at least one characteristic of the distortion in the voltage signal. For example, in the present embodiment, the phase B voltage signal 98 has two notches, one near distortion 102 and other near distortion 104. Thus, if meter 22 detects two distortions in its respective voltage signal it can determine that it is connected to phase B. Similarly, the phase A voltage signal has a notch in positive half cycle near distortion 102. So a meter 22 connected to phase A will observe a notch in a positive half cycle and can identify the corresponding phase as phase A. For phase C identification, meter 22 will observe a notch in the negative half cycle of the voltage signal 100 i.e., near distortion 104. It should be noted that the distortions represented in FIG. 4 are only an example, that the distortions may also be created at other points, and that meters 22 may be trained accordingly.

It should be noted that in certain embodiments, a three phase transformer may be present in between the meter and the system that modifies the distortions in voltage signals. However, in such cases phase shifts in voltage distortions due to these transformers may be accounted apriori and the meters 22 may be trained accordingly.

Unless defined otherwise, technical and scientific terms used herein have the same meaning as is commonly understood by one of skill in the art to which this invention belongs. The terms “first”, “second”, and the like, as used herein do not denote any order, quantity, or importance, but rather are used to distinguish one element from another. Also, the terms “a” and “an” and “the” do not denote a limitation of quantity, but rather denote the presence of at least one of the referenced item. For example, in reference to “a characteristic of the distortion,” one or more characteristics and one or more distortions may be used.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A phase identification system, comprising:
a power distribution station including a phase distortion device to generate distortions at cross over points of at least two pairs of three phase voltages; and
a phase detection device configured to receive one of the three phase voltages and to identify a phase of the received voltage based on a characteristic of a distortion in the received voltage.

2. The system of claim 1, wherein the phase detection device comprises a power meter.

3. The system of claim 1, wherein the phase detection device comprises a hand-held metering device.

4. The system of claim 1, wherein the characteristic of the distortion in the received voltage comprises a number of distortions and an instant of the distortion in the received voltage.

5. The system of claim 1, wherein the phase distortion devices comprises a voltage distortion circuitry.

6. The system of claim 5, wherein the voltage distortion circuitry comprises an antiparallel thyristor pair or a thyristor with an inductor or a resistor inductor pair connected between two phases.

7. The system of claim 5, wherein the voltage distortion circuitry comprises an antiparallel thyristor pair or a thyristor with a step down transformer connected between two phases.

8. The system of claim 1, wherein the phase detection device detects a first phase if the distortion is in a positive half cycle, a second phase if the distortion is in a negative half cycle, and a third phase if two distortions are present in the positive and negative half cycles.

9. The system of claim 1, wherein the phase detection device comprises a communication circuitry including a wireless transmitter or a power line carrier communication (PLC) circuitry to transmit a signal indicative of the phase of the received voltage to the power distribution station.

10. The system of claim 1, wherein the phase detection device is further configured to store a signal indicative of the phase of the received voltage and provide the signal to a utility.

11. The system of claim 1, wherein the distortions are generated upon command, on a schedule, or both upon command and on a schedule.

12. A method of identifying phase comprising:
receiving a distorted voltage from a power distribution system, wherein the distorted voltage was formed by distorting three phase voltages of the power distribution system near cross over points of at least two different pairs of the three phase voltages; and
determining information regarding a phase of the received distorted voltage based on a characteristic of a distortion in the received distorted voltage.

13. The method of claim 12, wherein distorting the three phase voltages comprises generating a notch in the three phase voltages by short circuiting two of the three phases momentarily through an inductor or a resistor inductor pair.

14. The method of claim 13, wherein short circuiting the two phases comprises switching solid state devices to connect the inductor or the resistor inductor pair in between the two phases.

15. The method of claim 14, wherein each of the solid state devices comprises multiple low voltage solid state devices connected in series.

16. The method of claim 12, wherein a characteristic of the distortion in the received voltage comprises a number of distortions.

17. The method of claim 12, wherein a characteristic of the distortion in the received voltage comprises an instant of the distortion.

18. The method of claim 12, wherein determining information regarding the phase of the received distorted voltages comprises identifying a first phase if the distortion is in a positive half cycle, a second phase if the distortion is in a negative half cycle, and a third phase if two distortions are present in the positive and negative half cycles.

19. The method of claim 12, further comprising transmitting the signal indicative of the phase of the voltage.
